(19) United States
(12) Patent Application Publication
(10) Pub. No.: US 2026/0104458 A1
(43) Pub. Date: Apr. 16, 2026

(54) METHOD AND APPARATUS FOR FUSION DETECTION IN VEHICLE BATTERY CHARGING SYSTEM

(71) Applicants: Hyundai Motor Company, Seoul (KR); Kia Corporation, Seoul (KR)

(72) Inventors: Jin Su Hong, Hwaseong-si (KR); Gi Bum Kim, Hwaseong-si (KR); Yong Jae Lee, Hwaseong-si (KR); Jun Yong Lee, Seongnam-si (KR); Dong Jun Lee, Suwon-si (KR); Ho Joon Shin, Hwaseong-si (KR)

(21) Appl. No.: 19/068,548

(22) Filed: Mar. 3, 2025

(30) Foreign Application Priority Data
Oct. 11, 2024 (KR) 10-2024-0138834

(51) Int. Cl. G01R 31/327; B60L 53/10; B60L 53/16; B60L 53/24; B60L 53/62

(52) U.S. Cl. CPC G01R 31/3278; B60L 53/11; B60L 53/16; B60L 53/24; B60L 53/62

(57) ABSTRACT

In a method and apparatus for fusion detection in a vehicle battery charging system, the apparatus can include an inlet sharing DC/AC charging ports, a DC charging system connected to a first conduction path from the inlet, having a motor and inverter, a first relay group having a first and second relay, arranged along the first path to connect the inlet with the DC charging system, an AC charging system connected to a second conduction path from the inlet, a second relay group having a third and fourth relay, arranged along the second path to connect the inlet with the AC charging system, and a controller configured to close all relays except the target relay, provide a constant voltage in DC or AC charging system connected to the target relay, and measure voltage at the input terminal of the other charging system to detect fusion in one of the relays.

### CROSS-REFERENCE TO RELATED APPLICATIONS

The present application claims priority of Korean Patent Application No. 10-2024-0138834 filed on Oct. 11, 2024, the entire contents of which are incorporated herein for all purposes by this reference.

### TECHNICAL FIELD

The present disclosure relates to a method and apparatus for fusion detection in a vehicle battery charging system.

### BACKGROUND

In general, electric vehicles or hybrid vehicles include an energy storage system (such as a battery) that receives and stores alternating current (AC) grid power through charging facilities. For charging the energy storage system, the vehicle includes a charging system that converts the AC grid power supplied from an external charging facility into direct current (DC) power at the required level.

Among the technologies used in the vehicle's on-board charging systems, the North American Charging Standard (NACS) is a standard charging technology for electric vehicles widely used in North America. This NACS was developed by Tesla for its electric vehicle charger, the “Supercharger,” which supports both AC and DC power.

The NACS is widely used in North America due to fast charging speed and compatibility with various electric vehicle models, and many electric vehicle manufacturers have recently adopted the NACS.

In a NACS charging system that supports both slow and rapid charging as shown in FIG. 1, a single NACS inlet 130 may be used for both slow charging using a slow charger 110 and rapid charging using a rapid charger 120. When a low voltage for slowly charging the vehicle is input from an external source, power is supplied to a slow charging circuit 150 through a slow charging relay 140, and when a high voltage for rapidly charging the vehicle is input, power is supplied to a rapid charging circuit 170 through a rapid charging relay 160.

However, if one of the rapid charging relays 160 is fused in this NACS charging system, a leakage current may occur during slow charging, which may cause a charger to shut down. If one of the slow charging relays 140 is fused, an over-voltage may be input to the Integrated Charging Control Unit (ICCU), which may damage the ICCU.

Therefore, there is a need in this technical field for a technique to detect relay fusion in a vehicle battery charging system that supports the NACS.

### SUMMARY

Example embodiments of the present disclosure relate to an eco-friendly vehicle charging technology, and more particularly, to a method and apparatus for fusion detection in a vehicle battery charging system.

An embodiment of the present disclosure can detect relay fusion in a vehicle battery charging system that supports the North American Charging Standard (NACS).

An embodiment of the present disclosure can detect relay fusion using an inverter and on-board charger (OBC) without a separate diagnostic control circuit for fusion detection.

The technical advantages disclosed in embodiments of the present disclosure are not necessarily limited to the aforementioned technical advantages, and unmentioned or other technical advantages can be appreciated by those skilled in the art from the following description.

An apparatus for fusion detection according to an embodiment of the present disclosure can include an inlet configured to share a direct current (DC) charging port and an alternating current (AC) charging port, a DC charging system electrically connected to a first conduction path branched from the inlet and configured to include a motor and an inverter, a first relay group configured to include a first relay and a second relay, which are arranged along the first conduction path to selectively connect the inlet with the DC charging system, an AC charging system electrically connected to a second conduction path branched from the inlet, a second relay group configured to include a third relay and a fourth relay, which are arranged along the second conduction path to selectively connect the inlet with the AC charging system, and a controller configured to close all relays except a relay targeted for detection, provide a constant voltage in either the DC charging system or the AC charging system connected to the relay targeted for detection, and measure a voltage detected at an input terminal of a different charging system than the one connected to the relay targeted for detection, to detect fusion in one of the first to fourth relays.

In an embodiment, the first conduction path may include a DC (+) line and a DC (−) line. The first relay may be arranged on the DC (+) line, and the second relay may be arranged on the DC (−) line.

In an embodiment, the second conduction path may include an AC1 line and an AC2 line. The third relay may be arranged on the AC1 line, and the fourth relay may be arranged on the AC2 line.

In an embodiment, the controller may control the constant voltage to be provided at a neutral terminal of the motor when detecting fusion of a relay in the first relay group.

In an embodiment, the controller may control the constant voltage to be provided in the DC charging system when detecting fusion of a relay in the second relay group.

In an embodiment, the controller may determine fusion based on a voltage measured at the input terminal of the AC charging system when the relay targeted for detection is in the first relay group.

In an embodiment, the controller may determine that the relay targeted for detection is fused when the voltage measured at the input terminal of the AC charging system is higher than or equal to a threshold voltage.

In an embodiment, the controller may determine fusion based on a voltage measured at the input terminal of the DC charging system when the relay targeted for detection is in the second relay group.

In an embodiment, the controller may determine that the relay targeted for detection is fused when the voltage measured at the input terminal of the DC charging system is higher than or equal to a threshold voltage.

A method for fusion detection according to an embodiment of the present disclosure can include closing all relays except a relay targeted for detection to detect fusion of a first relay and a second relay, included in a first relay group and arranged along a first conduction path branched from an inlet that shares a DC charging port and an AC charging port to selectively connect the inlet with a DC charging system and to detect fusion of either the third relay or the fourth relay, included in a second relay group and arranged along a second conduction path branched from the inlet to selectively connect the inlet with an AC charging system, providing a constant voltage in either the DC charging system or the AC charging system connected to the relay targeted for detection, and measuring a voltage detected at an input terminal of a different charging system than the one connected to the relay targeted for detection.

In an embodiment, the providing of a constant voltage may include controlling the constant voltage to be provided at a neutral terminal of a motor when detecting fusion of a relay in the first relay group.

In an embodiment, the providing of a constant voltage may include controlling the constant voltage to be provided in the DC charging system when detecting fusion of a relay in the second relay group.

In an embodiment, the measuring of a voltage detected may include determining fusion based on a voltage measured at the input terminal of the AC charging system when the relay targeted for detection is in the first relay group.

In an embodiment, the measuring of the voltage detected may include determining that the relay targeted for detection is fused when the voltage measured at the input terminal of the AC charging system is higher than or equal to a threshold voltage.

In an embodiment, the measuring of a voltage detected may include determining fusion based on a voltage measured at the input terminal of the DC charging system when the relay targeted for detection is in the second relay group.

In an embodiment, the measuring of the voltage detected may include determining that the relay targeted for detection is fused when the voltage measured at the input terminal of the DC charging system is higher than or equal to a threshold voltage.

With various embodiments of the present disclosure, as described above, it can be possible to detect relay fusion in a vehicle battery charging system that supports the NACS.

With various embodiments of the present disclosure, it can be possible to detect fusion of a relay using the inverter and OBC without a separate diagnostic control circuit for fusion detection.

### BRIEF DESCRIPTION OF THE DRAWINGS

FIG. 1 shows an example of a North American Charging Standard (NACS) charging system that supports both slow charging and rapid charging, to which an embodiment of the present disclosure may be applied.

FIG. 2 shows an example of an apparatus for fusion detection according to an embodiment of the present disclosure.

FIG. 3 shows an example of detecting fusion of a first relay group based on on/off states of its respective relays and a voltage measured by a voltage sensor in the apparatus for fusion detection of the embodiment of FIG. 2.

FIG. 4 shows an example of detecting fusion of a second relay group based on on/off states of its respective relays and a voltage measured by a voltage sensor in the apparatus for fusion detection of the embodiment of FIG. 2.

FIG. 5 is a block diagram schematically showing an example of an apparatus for fusion detection according to an embodiment of the present disclosure.

FIGS. 6 and 7 are flowcharts showing a method for fusion detection in a vehicle battery charging system according to an embodiment of the present disclosure.

FIGS. 8 and 9 are flowcharts showing a method for fusion detection in a vehicle battery charging system according to an embodiment of the present disclosure.

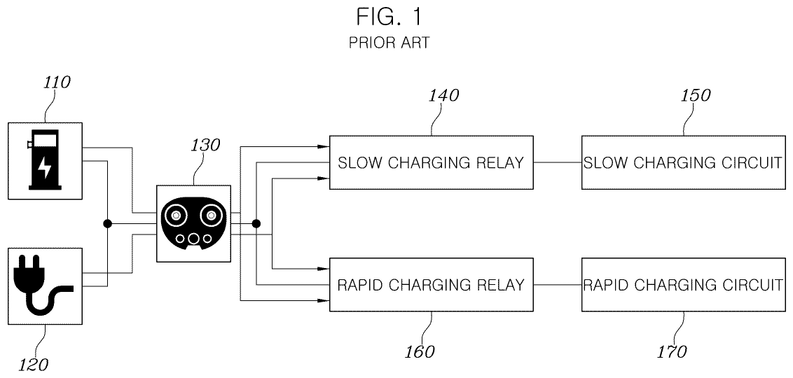

### DETAILED DESCRIPTION OF ILLUSTRATIVE EMBODIMENTS

Hereinafter, example embodiments disclosed in the present specification will be described in detail with reference to the drawings. Same reference numerals can be given to same or similar components regardless of reference numerals, and a repetitive description thereof can be omitted. As used in the following description, suffixes “module” and “part” for a component can be used or interchangeably used solely for ease of preparation of the specification, and do not have different meanings and each of them does not function by itself. In describing example embodiments disclosed in the present specification, when a detailed description of a known related art is determined to potentially obscure the gist of the example embodiments disclosed in the present specification, the detailed description thereof can be omitted herein. The accompanying drawings are merely for easy understanding of the example embodiments disclosed in the present specification, the technical spirit disclosed in the present specification is not necessarily limited by the accompanying drawings, and it can be understood to include all modifications, equivalents, and substitutes included in the spirit and scopes of the present disclosure.

Terms including ordinal numbers such as “first,” “second,” and the like, used herein may be used to describe various components, but the various components are not necessarily limited by these terms. These terms can be used merely for the purpose of distinguishing one component from another component.

When a component is referred to as being “connected” or “coupled” to another component, the component may be directly connected or coupled to another component, but it should be understood that sill another component may be present between the component and another component. Conversely, when a component is referred to as being “directly connected” or “directly coupled” to another, it should be understood that still another component may not be present between the component and another component.

Unless the context clearly dictates otherwise, the singular form can include the plural form.

In the present specification, the terms “comprising,” “having,” or the like are used to specify that a feature, a number, a step, an operation, a component, an element, or a combination thereof described herein exists, and they do not preclude the presence or addition of one or more other features, numbers, steps, operations, components, elements, or combinations thereof.

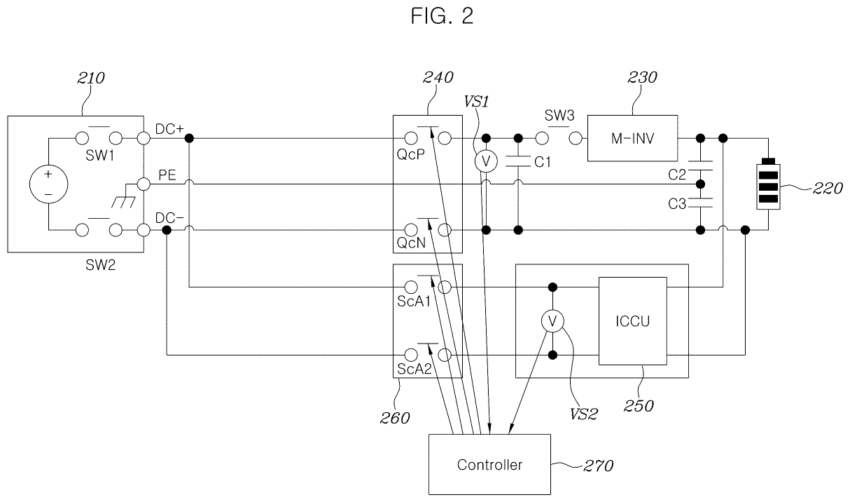

FIG. 2 shows an example of an apparatus for fusion detection according to an embodiment of the present disclosure.

Referring to FIG. 2, an apparatus for fusion detection according to an embodiment of the present disclosure can include: an inlet 210 connected to an external power source to receive power; a first switch SW1 and a second switch SW2 that control power supply within the inlet 210; a battery 220 that charges power using the external power source connected to the inlet 210 and supplies power from the charged energy when a vehicle is in operation; a direct current (DC) charging system 230 electrically connected to a first conduction path branched from the inlet 210; a first relay group 240 arranged along the first conduction path; an alternating current (AC) charging system 250 electrically connected to a second conduction path branched from the inlet 210; a second relay group 260 arranged along the second conduction path; a first voltage sensor VS1 that measures a voltage at an input terminal of the DC charging system 230; a second voltage sensor VS2 that measures a voltage at an input terminal of the AC charging system 250; and a controller 270 configured to control the first relay group 240, the second relay group 260, the first voltage sensor VS1, and the second voltage sensor VS2 to detect fusion of a relay in either the first relay group or the second relay group.

In this example, FIG. 2 shows that the inlet 210 receives power from a DC power source. However, the inlet 210 may share a DC charging port and an AC charging port to receive power either from a DC power source for rapid charging or from an AC power source for slow charging.

In this example, a conduction path configured to connect from the inlet 210 to the battery 220 branches into the first conduction path and the second conduction path.

In this example, the first conduction path includes a DC (+) line and a DC (−) line. The first relay group can include a first relay QcP on the DC (+) line and a second relay QcN on the DC (−) line.

The second conduction path can include an AC1 line and an AC2 line. The second relay group can include a third relay ScA1 on the AC1 line and a fourth relay ScA2 on the AC2 line.

In this example, the DC charging system 230 may include a motor and an inverter.

In this example, when a voltage of DC charging power supplied from the external source is suitable for charging the battery 220, the DC charging system 230 may operate as follows: if the charging voltage is higher than the battery 220 voltage, the DC charging power can be directly transferred to the battery 220 without voltage boosting; if the charging voltage is lower than the battery 220 voltage, the charging power may be input through a neutral point of the motor and boost the voltage of the charging power through a boost converter topology configured with motor windings and inverter switches, thereby charging the battery 220.

In this example, the AC charging system 250 may be an on-board charger (OBC) of the vehicle or a corresponding configuration. For example, the AC charging system 250 may be implemented as an OBC or as an integrated charging control unit (ICCU) that integrates the OBC and a DC-DC converter.

In this example, the first relay QcP and the second relay QcN may be arranged along the first conduction path branched from the inlet 210 to selectively connect the inlet 210 with the DC charging system 230.

In this example, the third relay ScA1 and the fourth relay ScA2 may be arranged along the second conduction path branched from the inlet 210 to selectively connect the inlet 210 with the AC charging system 250.

The controller 270 can be configured to control the first to fourth relays QcP, QcN, ScA1, ScA2 and to detect fusion of the first to fourth relays QcP, QcN, ScA1, ScA2 based on voltage measurements of the first voltage sensor VS1 and the second voltage sensor VS2.

In this example, before receiving power from the external power source connected to the inlet 210, that is, when the power supply from the external power source is disconnected, the controller 270 may be configured to short-circuit the third relay ScA1 and the fourth relay ScA2 and to short-circuit either the first relay QcP or the second relay QcN to determine whether the remaining relay, either the first relay QcP or the second relay QcN, is fused.

Fusion can mean that a switch is closed when the switch should be open. If either the first relay QcP or the second relay QcN is fused, no voltage should be applied to the AC charging system 250, even after short-circuiting either the first relay QcP or the second relay QcN when the third ScA1 and the fourth relay ScA2 are short-circuited.

Conversely, when the power supply from the external power source connected to the inlet 210 is disconnected, the controller 270 may be configured to short-circuit the first relay QcP and the second relay QcN and to short-circuit either the third relay ScA1 or the fourth relay ScA2 to determine whether the remaining relay, either the third relay ScA1 or the fourth relay ScA2, is fused.

If either the third relay ScA1 or the fourth relay ScA2 is fused, no voltage should be applied to the DC charging system 230, even after short-circuiting either the third relay ScA1 or the fourth relay ScA2 when the first relay QcP and the second relay QcN are short-circuited.

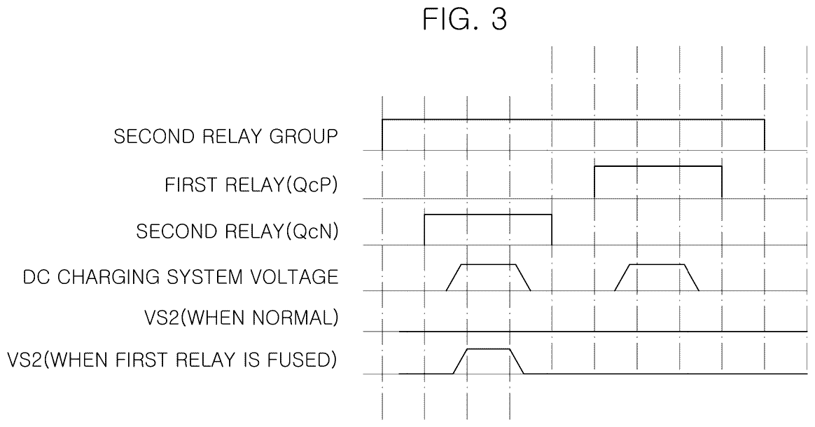

FIG. 3 shows an example of detecting fusion of a first relay group based on on/off states of its respective relays and a voltage measured by a voltage sensor in the apparatus for fusion detection of the embodiment of FIG. 2.

FIG. 3 shows an example of detecting fusion of a first relay based on on/off states of its respective relays and a voltage measured by a voltage sensor in the apparatus for fusion detection of the embodiment of FIG. 2.

Referring to FIG. 3 along with FIG. 2, when the power supply from the inlet 210 is disconnected, and the third relay ScA1 and the fourth relay ScA2, which are the second relay group 260, are short-circuited, if the first relay QcP is open, the second relay QcN is short-circuited, and voltage is provided at the neutral terminal of the motor (not shown) that constitutes the DC charging system 230, the voltage of the second voltage sensor VS2 is measured as 0 under normal conditions.

However, if the first relay QcP is fused, opening the first relay QcP has the same effect as a short circuit occurs, resulting in a constant voltage being measured by the second voltage sensor VS2.

In this example, a voltage identical to the voltage provided at the neutral terminal of the motor may be measured by the second voltage sensor VS2.

For example, if the voltage provided at the neutral terminal of the motor is 60 V, a voltage of 60 V may also be measured by the second voltage sensor VS2.

Even though the first relay QcP is fused, when the third relay ScA1 and the fourth relay ScA2, which are the second relay group 260, are short-circuited, if the second relay QcN is open, and the first relay QcP is short-circuited, the second relay QcN that is not fused remains open. Therefore, when voltage is provided at the neutral terminal of the motor (not shown) that constitutes the DC charging system 230, the voltage of the second voltage sensor VS2 is consistently measured as 0.

Similarly, when the power supply from the inlet 210 is disconnected, and the third relay ScA1 and the fourth relay ScA2, which are the second relay group 260, are short-circuited, if the first relay QcP is short-circuited, the second relay QcN is open, and voltage is provided at the neutral terminal of the motor (not shown) that constitutes the DC charging system 230, it is also possible to detect whether the second relay is fused based on the voltage measured by the second voltage sensor VS2.

Therefore, when the second relay group 260 is short-circuited, if either the first relay QcP or second relay QcN, which constitute the first relay group 240, is short-circuited, and voltage is provided at the neutral terminal of the motor (not shown) that constitutes the DC charging system 230, it is possible to determine whether the remaining relay in the first relay group 240 is fused based on the voltage value measured by the second sensor VS2.

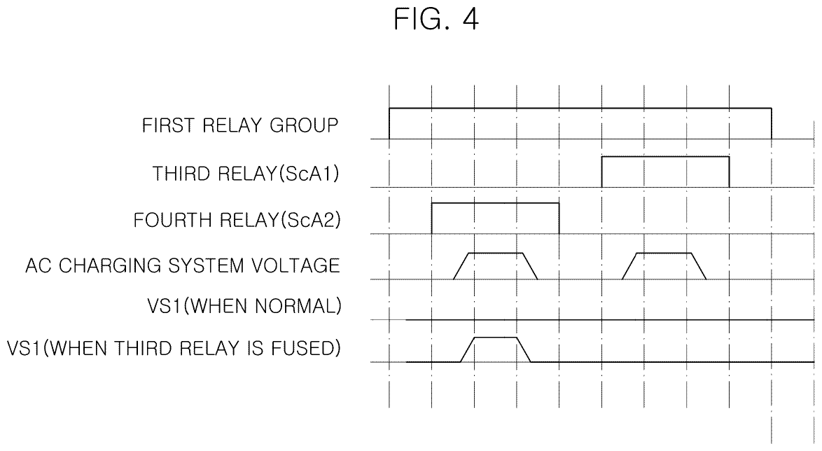

FIG. 4 shows an example of detecting fusion of a third relay based on on/off states of its respective relays and a voltage measured by a voltage sensor in the apparatus for fusion detection of the embodiment of FIG. 2.

Referring to FIG. 4 along with FIG. 2, when the power supply from the inlet 210 is disconnected, and the first relay QcP and the second relay QcN, which are the first relay group 240, are short-circuited, if the third relay ScA1 is open, the fourth relay ScA2 is short-circuited, and voltage is provided in the AC charging system 250, the voltage of the first voltage sensor VS1 is measured as 0 under normal conditions.

However, if the third relay ScA1 is fused, opening the third relay ScA1 has the same effect as a short circuit occurs, resulting in a constant voltage being measured by the first voltage sensor VS1.

In this example, a voltage identical to the voltage provided in the AC charging system 250 may be measured by the first voltage sensor VS1.

For example, if the voltage provided in the AC charging system 250 is 60 V, a voltage of 60 V may be measured by the first voltage sensor VS1.

Even though the third relay ScA1 is fused, when the first relay QcP and the second relay QcN, which are the first relay group 240, are short-circuited, if the fourth relay ScA2 is open, and the third relay ScA1 is short-circuited, the fourth relay ScA2 that is not fused remains open. Therefore, when voltage is provided at the neutral terminal of the motor (not shown) that constitutes the DC charging system 230, the voltage of the first voltage sensor VS1 is consistently measured as 0.

Similarly, when the power supply from the inlet 210 is disconnected and the first relay QcP and the second relay QcN, which are the first relay group 240, are short-circuited, if the third relay ScA1 is short-circuited, the fourth relay ScA2 is open, and voltage is provided in the AC charging system 250, it is also possible to detect whether the fourth relay is fused based on the voltage measured by the first voltage sensor VS1.

Therefore, when the first relay group 240 is short-circuited, if either the third relay ScA1 or the fourth relay ScA2, which constitute the second relay group 260, is short-circuited, and voltage is provided in the AC charging system 250, it is possible to determine whether the remaining relay in the second relay group 260 is fused based on the voltage value measured by the first voltage sensor VS1.

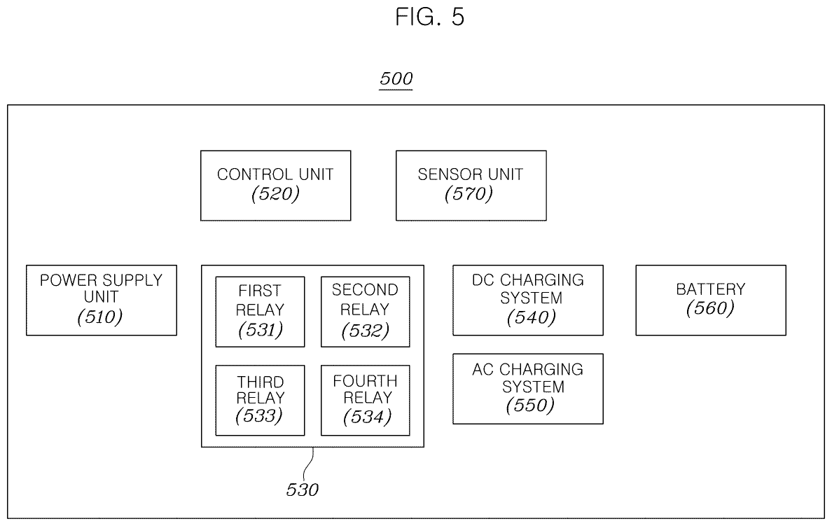

FIG. 5 is a block diagram schematically showing an example of an apparatus for fusion detection according to another embodiment of the present disclosure.

Referring to FIG. 5, an apparatus for fusion detection 500 according to an embodiment of the present disclosure can include a power supply unit 510, a control unit 520, relays 530, a DC charging system 540, an AC charging system 550, a battery 560, and a sensor unit 570, any of, any combination of, or all of which may be in plural or may include plural components thereof.

The power supply unit 510 can supply power for charging the battery 560.

In this example, the power supply unit 510 may include a North American Charging Standard (NACS) inlet.

In this example, the inlet may share a DC charging port and an AC charging port to receive DC power from a DC voltage source or AC power from an AC voltage source.

When DC power is input to the power supply unit 510 from an external source, the control unit 520 can close a first relay group 531, 532 to charge the battery 560 through the DC charging system 540. When AC power is input, the control unit 520 can close a second relay group 533, 534 to charge the battery 560 through the AC charging system 550.

The control unit 520 may operate in a mode to detect fusion in one of the first to fourth relays 531, 532, 533, 534.

In this example, the control unit 520 may operate in a mode to detect fusion of the first relay 531 or the second relay 532 when AC power is input to the power supply unit 510 from an external source.

For example, in a mode to detect fusion of the first relay 531, the control unit 520 is configured to short-circuit the second relay 532, to provide a constant voltage in the DC charging system 540, and to detect a voltage at the input terminal of the AC charging system 550, when the third relay 533 and the fourth relay 534 are short-circuited.

In this example, the control unit 520 may be configured to provide a constant voltage at the neutral terminal of the motor included in the DC charging system 540.

In this example, if no voltage is measured at the input terminal of the AC charging system 550, the control unit 520 can determine that the first relay 531 is not fused.

In this example, if a voltage measured at the input terminal of the AC charging system 550 is higher than or equal to a threshold voltage, the control unit 520 can determine that the first relay 531 is fused.

In this example, the threshold voltage may be any voltage selected by a user to determine fusion of the first relay 531.

In a mode to detect fusion of the second relay 532, the control unit 520 can be configured to short-circuit the first relay 531, to provide a constant voltage in the DC charging system 230, and to detect a voltage at the input terminal of the AC charging system 550, when the third relay 533 and the fourth relay 534 are short-circuited.

In this example, the control unit 520 may be configured to provide a constant voltage at the neutral terminal of the motor included in the DC charging system 540.

In this example, if no voltage is measured at the input terminal of the AC charging system 550, the control unit 520 can determine that the second relay 532 is not fused.

In this example, if a voltage measured at the input terminal of the AC charging system 550 is higher than or equal to a threshold voltage, the control unit 520 can determine that the second relay 532 is fused.

In this example, the threshold voltage may be any voltage selected by a user to determine fusion of the second relay 532.

Furthermore, the control unit 520 may operate in a mode to detect fusion of the third relay 533 or the fourth relay 534 when DC power is input to the power supply unit 510 from an external source.

For example, in a mode to detect fusion of the third relay 533, the control unit 520 can be configured to short-circuit the fourth relay 534, to provide a constant voltage in the AC charging system 550, and to detect a voltage at the input terminal of the DC charging system 540, when the first relay 531 and the second relay 532 are short-circuited.

In this example, if no voltage is measured at the input terminal of the DC charging system 540, the control unit 520 can determine that the third relay 533 is not fused.

In this example, if a voltage measured at the input terminal of the DC charging system 540 is higher than or equal to a threshold voltage, the control unit 520 can determine that the third relay 533 is fused.

In this example, the threshold voltage may be any voltage selected by a user to determine fusion of the third relay 533.

In a mode to detect fusion of the fourth relay 534, the control unit 520 can be configured to short-circuit the third relay 533, to provide a constant voltage in the AC charging system 550, and to detect a voltage at the input terminal of the DC charging system 540, when the first relay 531 and the second relay 532 are short-circuited.

In this example, if no voltage is measured at the input terminal of the DC charging system 540, the control unit 520 can determine that the fourth relay 534 is not fused.

In this example, if a voltage measured at the input terminal of the DC charging system 540 is higher than or equal to a threshold voltage, the control unit 520 can determine that the fourth relay 534 is fused.

In this example, the threshold voltage may be any voltage selected by a user to determine fusion of the fourth relay 534.

The relays 530 can be short-circuited or open under the control of the control unit 520 and include the first to fourth relays 531, 532, 533, 534.

When DC power is input to the power supply unit 510, the DC charging system 540, under the control of the control unit 520, can convert the high-voltage DC power input to the power supply unit 510 to charge the battery 560.

When AC power is input to the power supply unit 510, the AC charging system 550, under the control of the control unit 520, can convert the low-voltage AC power input to the power supply unit 510 to charge the battery 560.

The battery 560 can charge power using the power supplied from the power supply unit 510 and provide power from the charged energy when the vehicle is in operation.

The sensor unit 570 can measure a voltage of the DC charging system 540 or the AC charging system 550 to detect fusion in the first to fourth relays 531, 532, 533, 534.

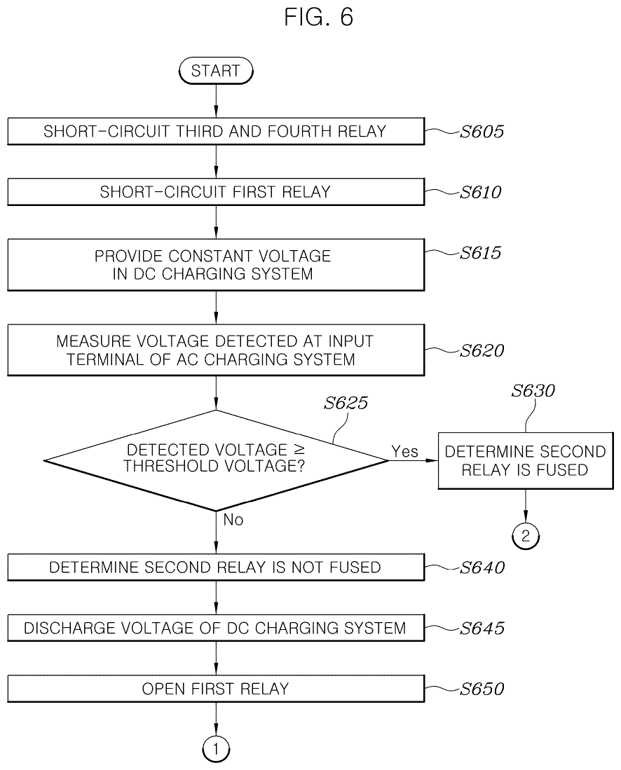

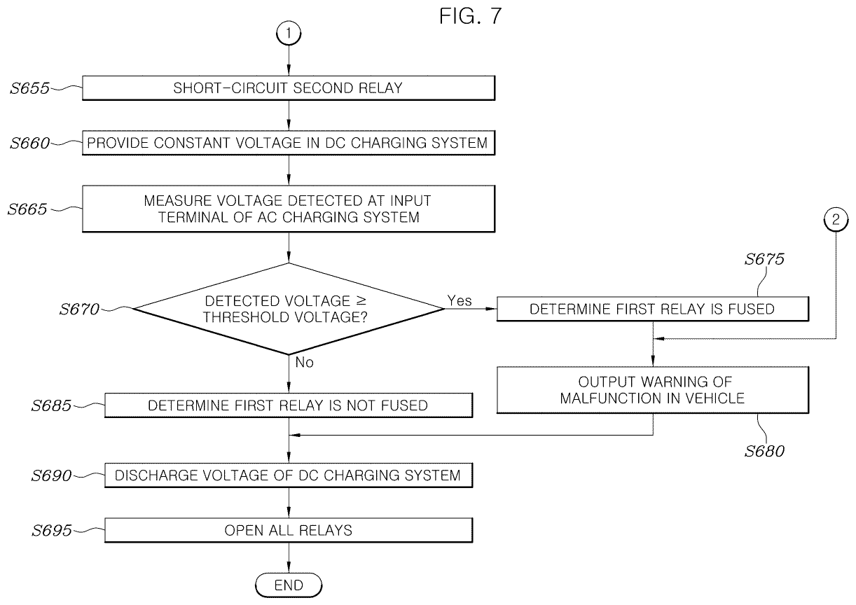

FIGS. 6 and 7 are flowcharts showing a method for fusion detection of a vehicle battery charging system according to an embodiment of the present disclosure.

The method for fusion detection according to an embodiment of the present embodiment may be performed by the controller 270 of the embodiment of FIG. 2.

Referring to FIGS. 6 and 7, the controller 270 can be configured to short-circuit the third relay ScA1 and the fourth relay ScA2 (operation S605) and to short-circuit the first relay QcP (operation S610) to detect whether the second relay QcN is fused.

The controller 270 can be configured to provide a constant voltage in the DC charging system 230 (operation S615) and to detect a voltage at the input terminal of the AC charging system 250 (operation S620).

At operation S615, the controller 270 may be configured to control a constant voltage to be provided at the neutral terminal of the motor included in the DC charging system 230.

The controller 270 can be configured to determine whether the voltage detected at the input terminal of the AC charging system 250 is higher than or equal to a threshold voltage (operation S625), and if the detected voltage is higher than or equal to the threshold voltage, to determine that the second relay QcN is fused (operation S630), to output a warning of a malfunction in the vehicle (operation S680), and to discharge the voltage of the DC charging system 230 (operation S690).

In this example, the warning of a malfunction in the vehicle may be given by displaying a warning message on a display screen within the vehicle or by outputting a warning sound through the vehicle's speakers.

On the other hand, if the detected voltage is lower than the threshold voltage as a result of the determination at operation S625, the controller 270 can be configured to determine that the second relay QcN is not fused (operation S640) and to discharge the voltage of the DC charging system 230 (operation S645). The controller 270 can be configured to open the first relay QcP (operation S650).

The controller 270 can be configured to short-circuit the second relay QcN (operation S655) to detect whether the first relay QcP is fused.

The controller 270 can be configured to provide a constant voltage in the DC charging system 230 (operation S660) and to measure a voltage detected at the input terminal of the AC charging system 250 (operation S665).

At operation S665, the controller 270 may control a constant voltage to be provided at the neutral terminal of the motor included in the DC charging system 230.

The controller 270 can be configured to determine whether the voltage detected at the input terminal of the AC charging system 250 is higher than or equal to a threshold voltage (operation S670), and if the detected voltage is higher than or equal to the threshold voltage, to determine that the first relay QcP is fused (operation S675), to output a warning of a malfunction in the vehicle (operation S680), and to discharge the voltage of the DC charging system 230 (operation S690).

In this example, the warning of a malfunction in the vehicle may be given by displaying a warning message on a display screen within the vehicle or by outputting a warning sound through the vehicle's speakers.

On the other hand, if the detected voltage is lower than the threshold voltage as a result of the determination at operation S670, the controller 270 can be configured to determine that the first relay QcP is not fused (operation S685) and to discharge the voltage of the DC charging system 230 (operation S690). The controller 270 can be configured to open all relays QcP, QcN, ScA1, ScA2.

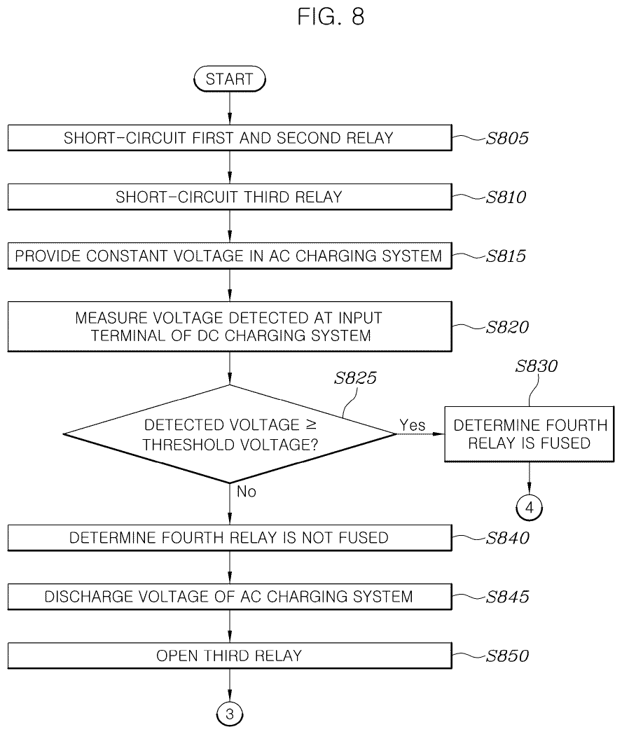

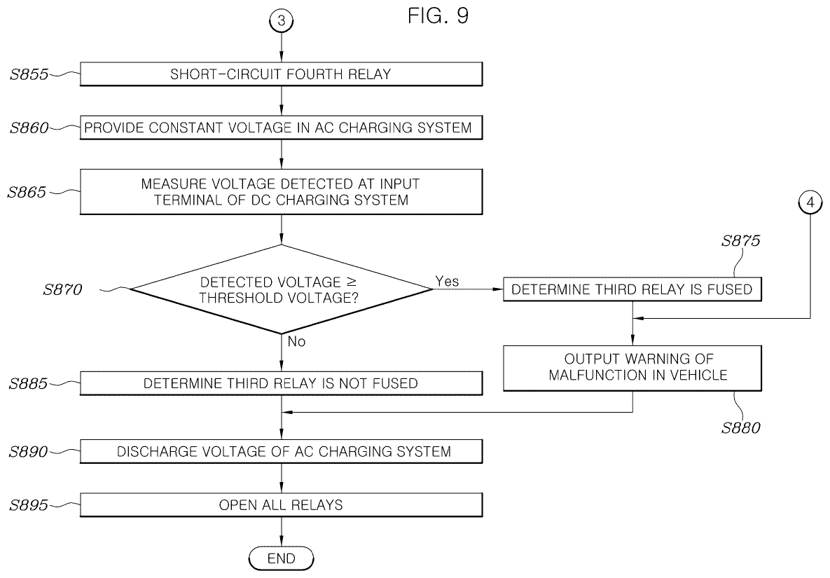

FIGS. 8 and 9 are flowcharts showing a method for fusion detection of a vehicle battery charging system according to an embodiment of the present disclosure.

The method for fusion detection according to an embodiment of the present embodiment may be performed by the controller 270 of the embodiment of FIG. 2.

Referring to FIGS. 8 and 9, the controller 270 can be configured to short-circuit the first relay QcP and the second relay QcN (operation S805) and to short-circuit the third relay ScA1 (operation S810) to detect whether the fourth relay ScA2 is fused.

The controller 270 can be configured to provide a constant voltage in the AC charging system 250 (operation S815) and to detect a voltage at the input terminal of the DC charging system 230 (operation S820).

The controller 270 can be configured to determine whether the voltage detected at the input terminal of the DC charging system 230 is higher than or equal to a threshold voltage (operation S825), and if the detected voltage is higher than or equal to the threshold voltage, to determine that the fourth relay ScA2 is fused (operation S830), to output a warning of a malfunction in the vehicle (operation S880), and to discharge the voltage of the DC charging system 230 (operation S890).

In this example, the warning of a malfunction in the vehicle may be given by displaying a warning message on a display screen within the vehicle and/or by outputting a warning sound through the vehicle's speakers.

On the other hand, if the detected voltage is lower than the threshold voltage as a result of the determination at operation S825, the controller 270 can be configured to determine that the fourth relay ScA2 is not fused (operation S840) and to discharge the voltage of the AC charging system 250 (operation S845). The controller 270 can be configured to open the third relay ScA1 (operation S850).

The controller 270 can be configured to short-circuit the fourth relay ScA2 (operation S855) to detect whether the third relay ScA1 is fused.

The controller 270 can be configured to provide a constant voltage in the AC charging system 250 (operation S860) and to detect a voltage at the input terminal of the AC charging system 250 (operation S865).

The controller 270 can be configured to determine whether the voltage detected at the input terminal of the DC charging system 230 is higher than or equal to a threshold voltage (operation S870), and if the detected voltage is higher than or equal to the threshold voltage, to determine that the third relay ScA1 is fused (operation S875), to output a warning of a malfunction in the vehicle (operation S880), and to discharge the voltage of the AC charging system 250 (operation S890).

In this example, the warning of a malfunction in the vehicle may be given by displaying a warning message on a display screen within the vehicle and/or by outputting a warning sound through the vehicle's speakers.

On the other hand, if the detected voltage is lower than the threshold voltage as a result of the determination at operation S870, the controller 270 can be configured to determine that the third relay ScA1 is not fused (operation S885) and to discharge the voltage of the AC charging system 250 (operation S890). The controller 270 can be configured to open all relays QcP, QcN, ScA1, ScA2 (operation S895).

With the example embodiments of the present disclosure described so far, it can be possible to detect fusion of a relay in an eco-friendly vehicle charging system that includes both slow charging relays and rapid charging relays.

With the example embodiments of the present disclosure described so far, it can be possible to detect fusion of a relay using the inverter and OBC without a separate diagnostic control circuit for fusion detection.

An embodiment of the present disclosure described above may be implemented as a computer-readable code on a program-recorded medium. A computer-readable medium can include any type of recording apparatus on which data is stored that can be read by a computer system. Examples of computer-readable media include hard disk drives (HDDs), solid state disks (SSDs), silicon disk drives (SDDs), ROMs, RAMs, CD-ROMs, magnetic tapes, floppy disks, and optical data storage apparatuses. Therefore, the above detailed description can be considered examples rather than necessarily restrictive. The scopes of the present disclosure can be determined by a reasonable interpretation of the appended claims, and all modifications within equivalent scopes of the present disclosure can be included within the scopes of the present disclosure.

What is claimed is:

1. An apparatus for relay fusion detection, the apparatus comprising:
an inlet configured to share a direct current (DC) charging port and an alternating current (AC) charging port;
a DC charging system electrically connected to a first conduction path branched from the inlet and configured to include a motor and an inverter;
a first relay group comprising a first relay and a second relay, wherein the first relay and the second relay are arranged along the first conduction path and configured to selectively connect the inlet with the DC charging system;
an AC charging system electrically connected to a second conduction path branched from the inlet;
a second relay group comprising a third relay and a fourth relay, wherein the third relay and the fourth relay are arranged along the second conduction path and configured to selectively connect the inlet with the AC charging system; and
a controller configured to:
close all of the first relay group and the second relay group, except a targeted relay being targeted for detection among the first relay group and the second relay group,
provide a constant voltage in either the DC charging system or the AC charging system connected to the targeted relay, and
measure a detected voltage detected at an input terminal of a different charging system than a given one connected to the targeted relay, to detect fusion in the targeted relay.

2. The apparatus of claim 1, wherein the first conduction path comprises a DC (+) line and a DC (−) line, wherein the first relay is arranged on the DC (+) line, and wherein the second relay is arranged on the DC (−) line.

3. The apparatus of claim 1, wherein the second conduction path comprises an AC1 line and an AC2 line, wherein the third relay is arranged on the AC1 line, and wherein the fourth relay is arranged on the AC2 line.

4. The apparatus of claim 1, wherein the controller is further configured to control the constant voltage to be provided at a neutral terminal of the motor in response to detecting fusion of the targeted relay being in the first relay group.

5. The apparatus of claim 1, wherein the controller is further configured to control the constant voltage to be provided in the DC charging system in response to detecting fusion of the targeted relay being in the second relay group.

6. The apparatus of claim 1, wherein the controller is further configured to determine fusion based on the detected voltage measured at the input terminal of the AC charging system in response to the targeted relay being in the first relay group.

7. The apparatus of claim 6, wherein the controller is further configured to determine that the targeted relay is fused in response to the detected voltage measured at the input terminal of the AC charging system being higher than or equal to a threshold voltage.

8. The apparatus of claim 1, wherein the controller is further configured to determine fusion based on the detected voltage measured at the input terminal of the DC charging system in response to the targeted relay being in the second relay group.

9. The apparatus of claim 8, wherein the controller is further configured to determine that the targeted relay is fused in response to the detected voltage measured at the input terminal of the DC charging system being higher than or equal to a threshold voltage.

10. A method for relay fusion detection, the method comprising:
closing all relays except a targeted relay being targeted for detection of relay fusion among the all relays, wherein the all relays comprises a first relay group including a first relay and a second relay, and a second relay group including a third relay and a fourth relay, wherein the first relay group is arranged along a first conduction path branched from an inlet, wherein the inlet shares a DC charging port and an AC charging port, wherein the first relay group is configured to selectively connect the inlet with a DC charging system via the DC charging port, wherein the second relay group is arranged along a second conduction path branched from the inlet, wherein the second relay group is configured to selectively connect the inlet with an AC charging system via the AC charging port;
providing a constant voltage in either of the DC charging system or the AC charging system being connected to the targeted relay; and
measuring a detected voltage detected at an input terminal of a different charging system than a one being connected to the targeted relay.

11. The method of claim 10, wherein the providing of the constant voltage comprises controlling the constant voltage to be provided at a neutral terminal of a motor in response to detecting fusion of the targeted relay being in the first relay group.

12. The method of claim 10, wherein the providing of the constant voltage comprises controlling the constant voltage to be provided in the DC charging system in response to detecting fusion of the targeted relay being in the second relay group.

13. The method of claim 10, wherein the measuring of the detected voltage comprises determining relay fusion based on the detected voltage measured at the input terminal of the AC charging system in response to the targeted relay being in the first relay group.

14. The method of claim 13, wherein the measuring of the detected voltage comprises determining that the targeted relay is fused in response to the detected voltage measured at the input terminal of the AC charging system being higher than or equal to a threshold voltage.

15. The method of claim 10, wherein the measuring of the detected voltage comprises determining relay fusion based on the detected voltage measured at the input terminal of the DC charging system in response to the targeted relay being in the second relay group.

16. The method of claim 15, wherein the measuring of the detected voltage comprises determining that the targeted relay is fused in response to the detected voltage measured at the input terminal of the DC charging system being higher than or equal to a threshold voltage.

17. A method for relay fusion detection, the method comprising:
closing all relays except a targeted relay being targeted for detection of relay fusion among the all relays, wherein the all relays comprises a first relay group including a first relay and a second relay, and a second relay group including a third relay and a fourth relay, wherein the first relay group is arranged along a first conduction path branched from an inlet, wherein the inlet comprises a DC charging port and an AC charging port, wherein the first relay group is configured to selectively connect the inlet with a DC charging system via the DC charging port, wherein the second relay group is arranged along a second conduction path branched from the inlet, wherein the second relay group is configured to selectively connect the inlet with an AC charging system via the AC charging port;
if the targeted relay is the second relay, such that the first relay, the third relay, and the fourth relay are controlled to be closed state, and such that the second relay is controlled to be open state, providing a first test voltage in the DC charging system, measuring a first detected voltage at an AC input terminal of the AC charging system, and determining that the second relay is fused in response to the first detected voltage being greater than a first threshold voltage or that the second relay is not fused in response to the first detected voltage being less than the first threshold voltage;
if the targeted relay is the first relay, such that the second relay, the third relay, and the fourth relay are controlled to be closed state, and such that the first relay is controlled to be open state, providing a second test voltage in the DC charging system, measuring a second detected voltage at the AC input terminal of the AC charging system, and determining that the first relay is fused in response to the second detected voltage being greater than a second threshold voltage or that the first relay is not fused in response to the second detected voltage being less than the second threshold voltage;
if the targeted relay is the fourth relay, such that the first relay, the second relay, and the third relay are controlled to be closed state, and such that the third relay is controlled to be open state, providing a third test voltage in the AC charging system, measuring a third detected voltage at a DC input terminal of the DC charging system, and determining that the fourth relay is fused in response to the third detected voltage being greater than a third threshold voltage or that the fourth relay is not fused in response to the third detected voltage being less than the third threshold voltage; and
if the targeted relay is the third relay, such that the first relay, the second relay, and the fourth relay are controlled to be closed state, and such that the third relay is controlled to be open state, providing a fourth test voltage in the AC charging system, measuring a fourth detected voltage at the DC input terminal of the DC charging system, and determining that the third relay is fused in response to the fourth detected voltage being greater than a fourth threshold voltage or that the third relay is not fused in response to the fourth detected voltage being less than the fourth threshold voltage.

18. The method of claim 17, wherein the all relays are tested in sequence, alternating which of the all relays is the targeted relay in sequence, respectively.

19. The method of claim 17, further comprising outputting a warning of malfunction in response to the targeted relay being determined to be fused.

20. The method of claim 17, further comprising selecting one of the all relays to be the targeted relay by a controller.
